(19) United States
(12) Patent Application Publication
(10) Pub. No.: US 2003/0155966 A1
(43) Pub. Date: Aug. 21, 2003

(54) Low-power, low-noise CMOS amplifier

(76) Inventor: Reid R. Harrison, Salt Lake City, UT (US)

Correspondence Address: KENNETH E. HORTON, RADER, FISHMAN & GRAUER PLLC, RIVERPARK CORPORATE CENTER ONE, 10653 SOUTH RIVERFRONT PARKWAY, SUITE 150, SOUTH JORDAN, UT, 84095, US

(21) Appl. No.: 10/080,950

(22) Filed: Feb. 20, 2002

(51) Int. Cl. H03F 1/02

(52) U.S. Cl. 330/9

(57) ABSTRACT

Devices and methods for amplifying weak electric signals are described. The device of the invention includes an amplifier that is fully integrated in a standard CMOS process and is capable of rejecting large DC offsets while amplifying signals down to the sub-Hz range. This result is achieved by using single-transistor MOS “pseudo-resistor” elements to achieve a very low cutoff frequency in the mHz range or lower. When combined with an electrode array or other sensor array, the fully-integrated amplifier is suitable for recording biological and biopotential signals from the mhz range up to and including about 7 kHz. The amplifier also rejects dc offsets at the input and offers a superior power-noise tradeoff than other amplifiers currently available.

### FIELD OF THE INVENTION

The invention generally relates to devices and methods for amplifying electric signals. More specifically, the invention relates to devices and methods for amplifying weak electric signals using a low-power, low-noise amplifier. In particular, the invention relates to a devices and methods for amplifying weak electric signals using an amplifier that is fully integrated in a standard CMOS process and that is capable of rejecting large DC offsets while amplifying signals down to the sub-Hz range.

BACKGROUND OF THE INVENTION

In recent years, there has been an increasing need for technologies that enable neuroscientists and medical personnel to observe the electrical activity in humans and animals, e.g., the neural activity (or activity of neurons) in the brain. Such neural activity is typically observed using recording systems and techniques containing-among other equipment-multi-electrode arrays and amplifying systems. Such recording systems and techniques are becoming standard in basic neuroscience research and the knowledge gained from such systems and techniques are enabling numerous clinical and neuroprosthetic applications.

Recent advances in MEMS technology have produced small (less than 4 mm in any dimension) arrays of microelectrodes containing up to 100 neural recording sites. Future generations of arrays with hundreds and even thousands of electrodes are currently being developed. This desired improvement has increased the need for smaller and more powerful amplifying systems to work in conjunction with the improved microelectrode arrays.

Integrated electronic technologies have been developed for more powerful amplification systems that allow small-scale amplification of weak bioelectrical signals. Such integrated electronic technologies are exemplified in, for example: Degrauwe et al. “A Micropower CMOS-Instrumentation Amplifier” IEEE J. Solid-State Circuits 20: 805-807, 1985; Van Peteghem et al. “Micropower High-Performance SC Building Block For Integrated Low-Level Signal Processing” IEEE J Solid-State Circuits 20: 837-844, 1985; Dorman et al. “A Monolithic Signal Processor For a Neurophysiological Telemetry System” IEEE J Solid-State Circuits 20: 1185-1193, 1985; Najafi et al. “An Implantable Multielectrode Array With On-Chip Signal Processing,” IEEE J Solid-State Circuits 21: 1035-1044, 1986; Steyaert et al., “A Micropower Low-Noise Monolithic Instrumentation Amplifier For Medical Purposes,” IEEE J. Solid-State Circuits 22: 1163-1168, 1987; Metting van Rijn et al. “High-Quality Recording of Bioelectric Events,” Med. & Biol. Eng. & Comput. 29:1035-1044, 1986; Ji et al. “An Implantable CMOS Circuit Interface For Multiplexed Microelectrode Recording Arrays,” IEEE J Solid-State Circuits 27: 433-443, 1992; Pancrazio et al. “Description and Demonstration of a CMOS Amplifier-Based-System With Measurement and Stimulation Capability For Bioelectrical Signal Transduction” Biosensors & Bioelectronics 13: 971-979, 1998; Martins et al. “A CMOS IC For Portable EEG Acquisition Systems,” IEEE Trans. Instrument. and Measurement 47: 1191-1196, 1998; and Steyaert et al. “Low-Noise Monolithic Amplifier Design: Bipolar Versus CMOS” Analog Integrated Circuits and Signal Processing 1: 9-19, 1991.

Unfortunately, existing amplification systems based on such integrated electronic technologies typically have either unacceptable noise levels or consume too much power to be fully implantable in large quantities, which will become necessary for the next generation of amplification equipment, especially those used to record neural or other biopotential signals. Extracellular neural signals have amplitudes ranging from 10 μV to 10 mV and with typical electrode impedances between 100 kΩ and 1 MΩ at 1 kHz. Due to electrochemical effects at the electrode-tissue interface, DC offsets of 1-2V are common between differential recording electrodes. Neural “spikes” often contain energy in the 100 Hz-7 kHz band and the energy of local field potentials (LFPs) extends below 1 Hz.

To operate under these conditions, some existing VLSI bioamplifier designs use off-chip capacitors—separate form the chip containing the remainder of the amplifier circuit—in the nF range, thereby obtaining a low-frequency cutoff that passes LFP signals while rejecting large dc offsets. This approach, however, is not feasible for large numbers of implanted electrodes that will be necessary for the next generation of recording systems because of size considerations.

SUMMARY OF THE INVENTION

The invention provides devices and methods for amplifying weak electric signals. The device of the invention includes an amplifier that is fully integrated in a standard CMOS process and is capable of rejecting large DC offsets while amplifying signals down to the sub-Hz range. This result is achieved by using single-transistor MOS “pseudo-resistor” elements to achieve a very low cutoff frequency in the mHz range or lower. When combined with an electrode array or sensor array, the fully-integrated amplifier is suitable for recording biological and biopotential signals from the mHz range up to and including about 7 kHz. The amplifier also rejects DC offsets at the input and offers a superior power-noise tradeoff than other amplifiers currently available.

### BRIEF DESCRIPTION OF THE DRAWINGS

FIGS. 1-8 are views of devices and methods for amplifying weak electric signals according to the invention, in which:

FIG. 1 illustrates one aspect of an amplifier according to the invention;

FIG. 2 illustrates the current-voltage relationship of a transistor component in an amplifier of the invention;

FIG. 3 depicts another aspect of an amplifier according to the invention;

FIG. 4 shows the transfer function of an amplifier according to the invention;

FIG. 5 depicts an amplifier's response to a low-frequency square wave in one aspect of the invention;

FIG. 6 illustrates an amplifier's noise power spectral density in one aspect of the invention;

FIG. 7 depicts an amplifier's input-referred noise as a function of time in one aspect of the invention; and

FIG. 8 depicts a comparison of current against noise curves for various known amplifiers and an amplifier according to one aspect of the invention.

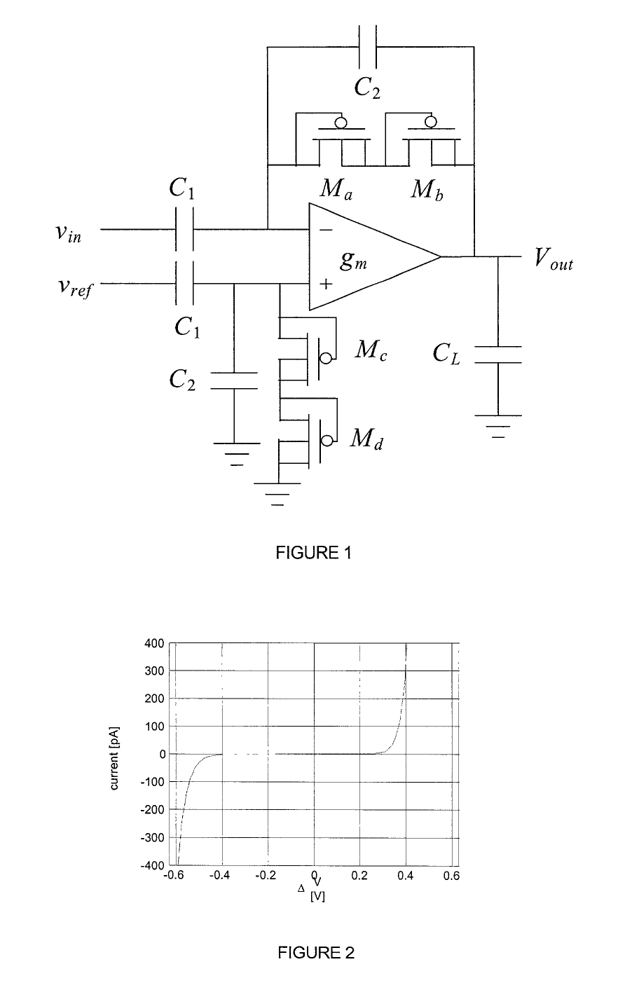

FIGS. 1-8 presented in conjunction with this description are views of only particular—rather than complete—portions of devices and methods for amplifying weak electric signals according to the invention.

### DETAILED DESCRIPTION OF THE INVENTION

The following description provides specific details in order to provide a thorough understanding of the invention. The skilled artisan will understand, however, that the invention can be practiced without employing these specific details. Indeed, the invention can be practiced by modifying the illustrated apparatus and method and can be used in conjunction with apparatus and techniques conventionally used in the industry. For example, the invention is described with respect to devices and methods for amplifying weak bioelectric signals. The invention described below, however, could be easily modified for any weak electric signals regardless of the source.

The invention includes a system for recording electrical signals. In one aspect of the intention, the system records bioelectrical signals using a sensor array (including an electrode array) and an amplifying system. The amplifying system contains an amplifier that is fully-integrated and able block the DC offsets while simultaneously maintaining the low-frequency information often contained in weak bioelectric signals.

Many biological signals (not to mention signals from many types of non-biological signals) are contained in low-frequency ranges (mHz to low Hz range). Many of these signals have important information in this low-frequency range, but are difficult to analyze and use because they also have large DC offsets. Many in the art have found it difficult using fully-integrated circuits to block the DC offsets while simultaneously maintaining the low-frequency information. Instead, they use off-chip capacitors to perform this function. Because the amplifier of the invention does not use off-chip capacitors, the amplifying system of the invention can be much smaller than those currently available.

The invention can be used for many types of electrical signals. In one aspect of the invention, the electrical signals are biological in nature (or bioelectrical signals). Such biological-based signals or bioelectrical signals would include: neural signals: biopotential signals like EMGs, EKGs, and EGGs; or other muscle signals. When used with such signals, the amplifiers are referred to as biosignal amplifiers, or bioamplifiers.

Any fully-integrated amplifying system that blocks DC offsets while simultaneously maintaining the low-frequency information in these low-frequency ranges can be used in the invention. In the invention, a “fully-integrated” amplifier is one in which all of the components of the amplifier—such as capacitors and transistors—are manufactured on a single chip. In one aspect of the invention, the amplifier depicted in FIG. 1 is employed in the invention. FIG. 1 is a schematic illustration of the circuit topology of this exemplary amplifier. The midband gain A_{M} of the amplifier is determined, in part, by the C₁/C₂ ratio. The gain of amplifier can generally range from about 1 to about 1000. Preferably, the gain of the amplifier ranges from about 20 to about 100.

In one aspect of the invention, the bandwidth of the amplifier can be represented by gₘ/(A_{M}C_{L}), where gₘ is the transconductance of the operational transconductance amplifier (OTA). The upper bandwidth limit of the amplifier of the invention can generally range from about 1 Hz to about 100 kHz. Preferably, the upper bandwidth limit of the amplifier ranges from about 30 Hz to about 30 kHz.

In the aspect of the invention illustrated in FIG. 1, transistors Mₐ, M_{b}, M_{c}, and M_{d} are MOS-bipolar devices acting as “pseudo-resistors”. In other words, with a negative voltage V_{GS}, these transistors function as diode-connected pMOS devices. And with a positive voltage V_{GS}, the parasitic source-well-drain pnp bipolar transistor is activated, and the device acts as a diode-connected bipolar device as illustrated in FIG. 2. Any transistor known in the art functioning in this manner can be employed as the Mₐ, M_{b}, M_{c}, and M_{d} transistors. In one aspect of the invention, each transistor is any single-transistor MOS “pseudo-resistor” element, such as those described in U.S. Pat. No. 5,376,813 as an adaptive element. Unlike that patent, the invention does not use this single-transistor for nonlinear adaptation. Instead, the transistor acts as a linear pseudo-resistor to achieve a very low cutoff frequency in the mHz range or lower.

The incremental resistance of the amplifier of the invention is relatively high. And for small voltages across the amplifier, the incremental resistance r_{inc} is extremely high. For example, for the amplifier illustrated in FIG. 1 and with an absolute voltage differential |ΔV| less than about 0.2V, the incremental resistance dV/dI is greater than 10¹¹ Ω. Preferably, the incremental resistance of the amplifier of the invention can be greater than about 10¹¹ Ω. For larger voltage differentials, such as 0.4V, the incremental resistance can range from about 10⁹ to about 10¹¹ Ω.

The amplifier of the invention can also reduce distortion for large output signals. In the aspect of the invention depicted in FIG. 1, two MOS-bipolar devices (Mₐ and M_{b} or M_{c} and M_{d}) are configured in series to reduce distortion for large output signals, e.g., signals having a voltage amplitude ranging from about 500 mV to about 1V. In the aspect of the invention depicted in FIG. 1, the low-frequency cutoff ω_{L} can be represented by 1/(2r_{inc}C₂).

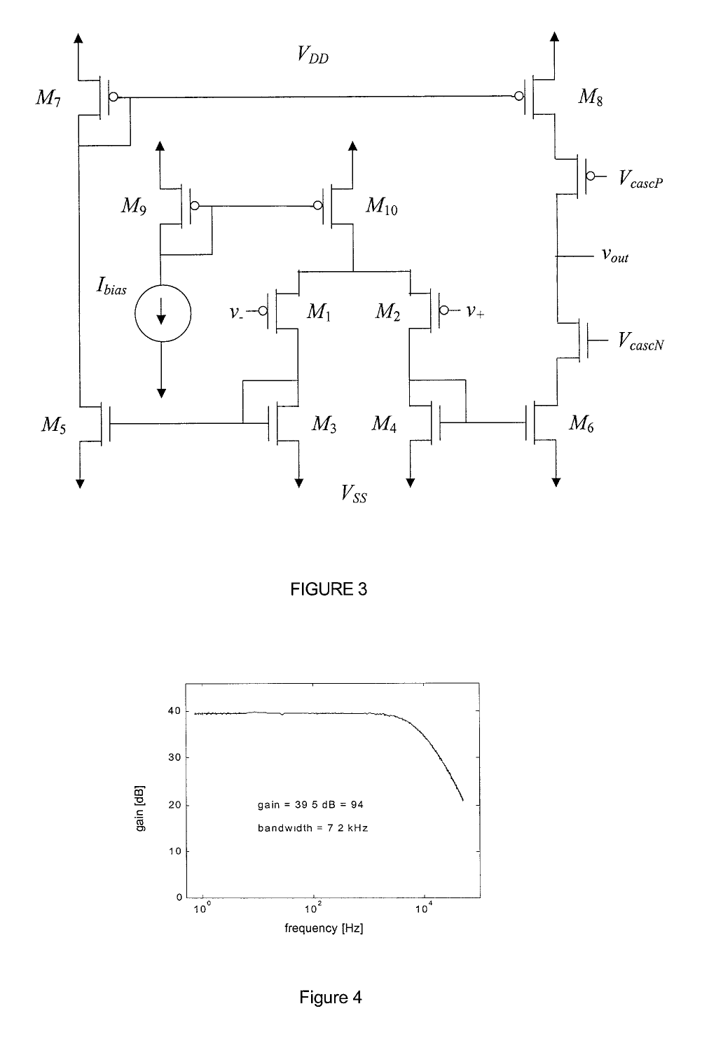

The OTA that can be used in the amplifier depicted in FIG. 1 can be any known in the art. The OTA uses any configuration of transistors that is suitable for driving capacitive loads, such as that configuration illustrated in FIG. 3 with transistors M₁ through M₁₀. The sizing of the transistors (width-to-length ratio, or W/L ratio), however, should be selected to achieve low noise at low current levels. In one aspect of the invention, the transistor sizes are selected to obtain an input-referred noise ranging from about 2.2 to about 3.6 μVrms when the bias current ranges from about 5 to about 20 μA. Accordingly, as described in more detail below, the transistor W/L ratio can range from about 100 to about 800 for transistors M₁ and M₂, from about 0.13 to about 0.5 for transistors M₃-M₆, and from about 0.13 to about 1 for transistors M₇ and M₈. Preferably, the transistor W/L ratio range is from about 150 to about 250 for transistors M₁ and M₂, from about 0.2 to about 0.4 for transistors M₃-M₆, and from about 0.25 to about 0.75 for transistors M₇ and M₈. In one aspect of the invention, the transistors may operate in either weak or strong inversion depending on their W/L ratio.

In one aspect of the invention, transistors M₁-M₈ have the same DC drain current. In this aspect of the invention, the transistors M₁ and M₂ (which operate as input devices in the OTA) can be configured with substantially similar sizes with a transconductance of gₘ₁ and a width-to-length ratio of (W/L)₁. Likewise, transistors M₃-M₆ can be configured with substantially similar sizes (W/L)₃ with a transconductance gₘ₃. The transistors M₇ and M₈ can be pMOS current mirror transistors and have substantially similar sizes (W/L)₇ with a transconductance gₘ₇.

Given these sizes and transconductances, the input-referred thermal noise power of the circuit depicted in FIG. 3 can be represented by formula (1):

$$\overline{{v}_{m , thermal}^{2}} = \frac{8 k T γ}{{g}_{m 1}} [ 1 + 2 \frac{{g}_{m 3}}{{g}_{m1}} + \frac{{g}_{m 7}}{{g}_{m 1}} ] . \qquad ( 1 )$$

By carefully selecting the W/L ratios of the respective transistors so that both gₘ₃ and gₘ₇ are substantially less than gₘ₁ (i.e., by a factor of about 10 to 20), the noise contributions of transistors M₃ through M₈ can be substantially reduced, e.g, by about 4. This “noise reduction” can be accomplished by making the W/L ratios of transistors M₃-M₆ [(W/L)₃] and the W/L ratios of transistors M₇ and M₈ [(W/L)₇] substantially less than the W/L ratios of transistors M₁ and M₂ [(W/L)₁], thereby pushing transistors M₃-M₈ into strong inversion (because their relative transconductance gₘ/ID in strong inversion decreases as 1/\sqrt{I_{D}}).

In certain aspects of the invention, it can be difficult to increase gₘ₃ and gₘ₇ arbitrarily without risking instability. When the capacitance seen by the gate of transistor M₃ (or M₄) is C₃, then the OTA illustrated in FIG. 3 has two poles at gₘ₃/C₃ and at gₘ₇/C₇. To increase stability, these two pole frequencies must be greater—and preferably several times greater—than the dominant pole gₘ₁/C_{L}. This condition becomes easier to accomplish as the capacitance C_{L} becomes larger, but this requires consideration of area limitations and bandwidth requirements.

The W/L ratios of the transistors is a tradeoff of several factors. The W/L ratio of the transistors M₃ through M₈ [(W/L)₃ and (W/L)₇] should be minimized as much as possible, thereby trading off phase margin for lower input-referred noise. However, the transistor gate area W·L should be as large as possible to minimize 1/f noise. But as transistors M₃ through M₈ are made larger, C₃ and C₇ increase, leading to a reduced phase margin. As well, as transistors M₁ and M₂ are made with larger gate areas, the input capacitance Cᵢₙ of the OTA (illustrated in FIG. 3) increases, resulting in more OTA noise.

In light of these tradeoffs, an optimum transistor size in the invention was determined in the following manner. To minimize noise within a given power range, the tradeoff between power and noise was quantified by the noise efficiency factor (NEF) represented by formula (2):

$$NEF = {V}_{m , r m s} \sqrt{\frac{2 {I}_{tot}}{π \cdot {U}_{T} \cdot 4 k T \cdot BW}} \qquad ( 2 )$$

where V_{ni,rms} is the input-referred rms noise voltage, Iₜₒₜ is the total amplifier supply current, U_{T} is the thermal voltage kT/q, and BW is the amplifier bandwidth. See, for example, the disclosure of Steyaert et al. (discussed above). In formula (2), an amplifier using a single bipolar transistor (with no 1/f noise) has an NEF of one. All practical circuits, however, have values higher than 1.

Substituting the expression for amplifier thermal noise integrated across the bandwidth BW from formula (1) into formula (2), and assuming that gₘ₃ and gₘ₇ are substantially less than gₘ₁ (i.e., by a factor of about 10 to 20), the NEF can be represented by formula (3):

$$NEF = \sqrt{\frac{2 γ {I}_{tot}}{{U}_{T} {g}_{m 1}}} = \sqrt{\frac{8 γ}{{U}_{T}} ( \frac{{I}_{D1}}{{g}_{m1}} )} \qquad ( 3 )$$

where I_{D1} is the drain current through M₁ (which is ¼ of the total amplifier supply current). Thus, to minimize the NEF, the relative transconductance gₘ/I_{D} of transistors M₁ and M₂ should be maximized.

In conditions of weak inversion, the relative transconductiance gₘ/I_{D} reaches its maximum value of κ/U_{T}. Under such conditions, the size of transistors M₁ and M₂ [(W/L)₁] are made large enough to ensure sub-threshold operation of the OTA with microamp current levels. Using the model for thermal noise valid in weak inversion described in Y. Tsividis (discussed above), NEF can be represented by formula (4):

$$NEF = \sqrt{\frac{4}{κ {U}_{T}} ( \frac{{I}_{D1}}{{g}_{m1}} )} \qquad ( 4 )$$

where κ is the sub-threshold gate coupling coefficient. In conditions of weak inversion, the expression for NEF reduces to formula (5):

$$NEF = \sqrt{\frac{4}{{κ}^{2}}} ≅ 2.9 \qquad ( 5 )$$

assuming a typical value of κ=0.7. Formula (5) represents the theoretical NEF limit for an amplifier with the circuit topology illustrated in FIG. 1 and FIG. 3 that has been constructed from MOS transistors. The NEF derived in formula (5) will, of course, be limited by constraints on gₘ₃ and gₘ₇ as discussed above, as well as by 1/f noise.

In other aspects of the invention, such as where the amplifier has a different circuit topology, the NEF will be different. As well, the optimum transistor size and other parameters of the amplifier will be different.

### EXAMPLE

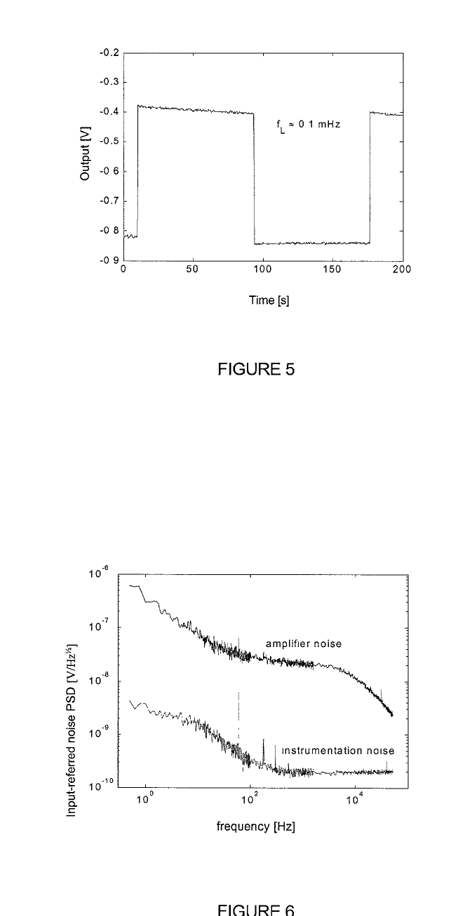

An amplifier in a 1.5 μm 2-poly commercially-available CMOS process was fabricated to be a fully-integrated circuit of dimensions 250 μm by 700 μm on a chip with dimensions of 2.2 mm by 2.2 mm. No external components such as capacitors or resistors are necessary for the circuit operation; all necessary circuit components are contained on the chip as an integrated circuit having dimensions of less than 1 mm by 1 mm. The amplifier was designed for a gain of 100, setting C₁ to 20 pF and C₂ to 200 fF. FIG. 4 shows the measured amplifier transfer function from 0.7 Hz to 50 kHz. The midband gain was measured to be 39.5 dB, slightly lower than the designed specification of 40 dB. This discrepancy is likely caused by fringing fields on the small C₂ capacitors, yielding a larger capacitance than designed. FIG. 5 shows the output of the amplifier in response to a 0.006 Hz square wave. Based on the slow adaptation of the output, the low-frequency cutoff f_{L} was estimated to be approximately 0.1 mHz.

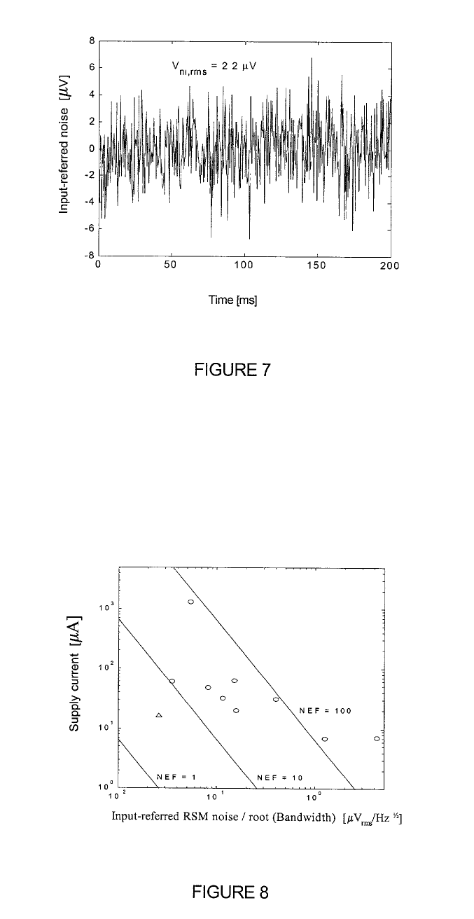

FIG. 6 shows the measured input-referred noise power spectral density (PSD). The thermal noise power was 21 nV/\sqrt{Hz} and the 1/f noise corner occured at 100 Hz. Integration under this curve yielded an rms noise voltage of 2.2 μVrms. This noise measurement was confirmed by recording the output noise waveform and dividing by the gain to generate an input-referred noise waveform whose rms value was 2.2 μVrms as depicted in FIG. 7. Table I compares these (and other) measurements along with the simulated results.

TABLE I
SIMULATED AND MEASURED CHARACTERISTICS
OF AMPLIFIER

| Parameter | Simulated | | Measured | |
|---|---|---|---|---|
| Supply voltage | 2.5 | V | 2.5 | V |
| Supply current | 16 | μA | 16 | μA |
| Gain | 40 | dB | 39.5 | dB |
| Bandwidth | 7.5 | kHz | 7.2 | kHz |
| Low-frequency cutoff | 130 | mHz | ˜0.1 | mHz |
| Input-referred noise | 3.1 | μVrms | 2.2 | μVrms |
| Noise efficiency factor | 5.6 | | 4.0 | |
| THD (16.7 mVpp input) | * | | 1.0% | |
| Dynamic range (%1 THD) | * | | 69 | dB |
| CMRR(10 Hz-5 kHz) | ≧42 | dB | ≧83 | dB |
| PSRR(10 Hz-5 kHz) | ≧42 | dB | ≧85 | dB |
| Crosstalk (f = 1 kHz) | * | | −64 | dB |
| Area (in 1.5 μm technology) | n/a | | 0.17 | mm² |

*Not Measured

The simulated noise levels exceeded those measured due to conservative estimates of 1/f noise coefficients. The NEF of the amplifier was 4.0, substantially near the theoretical limit of 2.9 calculated in formula (5). The distortion remained below 1% THD for inputs less than 16.7 mV peak-to-peak (larger than typical extracellular neural signals). The dynamic range was calculated assuming a distortion limit of 1% (a conservative definition) as 69 dB. Crosstalk was measured between amplifiers adjacent on the chip, and was −64 dB or less.

FIG. 8 shows the power-noise performance of this amplifier compared with estimated NEF values from conventional bioamplifiers. The amplifier of this Example presented here exhibits a better NEF than these conventional designs.

Having described the preferred aspects of the invention, it is understood that the invention defined by the appended claims is not to be limited by particular details set forth in the above description, as many apparent variations thereof are possible without departing from the spirit or scope thereof.

I claim:

1. A fully-integrated amplifier for amplifying electrical signals in the mHz to kHz range while rejecting large DC offsets.

2. The amplifier of claim 1, wherein the large DC offsets range up to several volts.

3. The amplifier of claim 1, the amplifier operating at a low noise of less than 20 μVrms.

4. The amplifier of claim 1, the amplifier operating with a low power of less than 1 mW, allowing many amplifiers to be fabricated on a single, low-power chip.

5. The amplifier of claim 1, wherein the amplifier is a bioamplifier for bioelectrical signals.

6. The amplifier of claim 5, the bioelectrical signals being neural signals, biopotential signals, or other muscle signals.

7. The amplifier of claim 1, comprising one or more MOS pseudo-resistors in series.

8. The amplifier of claim 7, wherein two or more MOS pseudo-resistors configured in series reduce the nonlinear distortion in the amplifier.

9. A biosignal amplifier comprising at least one MOS transistor or other circuit element having a large incremental resistance for small voltages that operates as a pseudo-resistor to amplify electrical signals down to the Hz and sub-Hz range while rejecting large DC offsets.

10. The amplifier of claim 9, wherein the biosignal amplifier is used for bioelelectrical signals.

11. The amplifier of claim 10, the bioelectrical signals being biopotential signals or neural signals.

12. The amplifier of claim 9, wherein the large DC offsets range up to several volts.

13. The amplifier of claim 9, the amplifier operating at a low noise of less than 20 μVrms.

14. The amplifier of claim 9, the amplifier operating with a low power of less than 1 mW.

15. The amplifier of claim 9, wherein at least one MOS transistor functions as a diode-connected pMOS device with a negative voltage and a diode-connected bipolar transistor with a positive voltage.

16. The amplifier of claim 9, further comprising two or more single-transistor MOS pseudo-resistors in series.

17. The amplifier of claim 16, wherein two or more MOS pseudo-resistors in series reduce the nonlinear distortion in the amplifier.

18. The amplifier of claim 15, wherein the use of small MOS pseudo-resistors to high-pass filter the signal at low frequencies allows for the construction of small integrated amplifiers.

19. An amplifying system, comprising a fully-integrated amplifier for amplifying electrical signals down to the Hz or sub-Hz range while rejecting large DC offsets.

20. An amplifying system, comprising a biosignal amplifier comprising at least one MOS transistor that operates as a pseudo-resistor to amplify electrical signals down to the Hz or sub-Hz range while rejecting large DC offsets.

21. The amplifying system of claim 20, the amplifier further comprising a pair of input transistors and at least one other transistor.

22. The amplifying system of claim 21, wherein the pair of input transistors are configured to operate in the sub-threshold regime and at least one other transistor is configured to operate above the threshold level.

23. A method for amplifying a neural or other biopotential signal, comprising:
providing a source of neural or other biopotential signals;
providing a fully-integrated amplifier for amplifying electrical signals in the mHz to kHz range while rejecting large DC offsets; and
electrically connecting the amplifier with the signal source.

24. The method of claim 21, the source of neural or other biopotential signals comprising an electrode array.

25. The method of claim 21, including electrically connecting the amplifier to the electrode array.

26. A method for amplifying a neural or other biopotential signal, comprising:
providing a source of neural or other biopotential signals;
providing a bioamplifier comprising at least one MOS transistor that operates as a pseudo-resistor to amplify electrical signals down to the Hz or sub-Hz range while rejecting large DC offsets; and
electrically connecting the amplifier with the neural signal source.

27. The method of claim 26, the source of neural or other biopotential signals comprising an electrode array.

28. The method of claim 27, including electrically connecting the bioamplifier to the electrode array.

29. The method of claim 26, the source of neural or other biopotential signals comprising a surface electrode array.

30. The method of claim 29, including electrically connecting the bioamplifier to surface electrodes.

31. A fully-integrated amplifier for amplifying electrical signals down to the Hz or sub-Hz range while rejecting large DC offsets, comprising one or more single-transistor MOS pseudo-resistors in series.

32. The amplifier of claim 31, wherein two or more single-transistor MOS pseudo-resistors reduce the nonlinear distortion in the amplifier.
